(19) United States
(12) Patent Application Publication
(10) Pub. No.: US 2026/0229444 A1
(43) Pub. Date: Aug. 6, 2026

(54) METHOD FOR OPERATING A MULTIPLE PARTICLE BEAM SYSTEM, CALIBRATION METHOD FOR A MULTIPLE PARTICLE BEAM SYSTEM, COMPUTER PROGRAM PRODUCT AND MULTIPLE PARTICLE BEAM SYSTEM WITH INCREASED PERFORMANCE

(71) Applicant: Carl Zeiss MultiSEM GmbH, Oberkochen (DE)

(72) Inventors: Christof RIEDESEL, Aalen (DE); Claudia SPIES, Neu-Ulm (DE); Walter PAULS, Huettlingen (DE); Paul Martin WEIRICH, Wehrheim (DE); Ingo MUELLER, Aalen (DE)

(21) Appl. No.: 19/576,230

(22) Filed: Mar. 24, 2026

Related U.S. Application Data
(63) Continuation of application No. PCT/EP2024/025272, filed on Sep. 13, 2024.

(30) Foreign Application Priority Data
Sep. 27, 2023 (DE) 10 2023 126 251.3

(51) Int. Cl. H01J 37/147; H01J 37/21; H01J 37/22; H01J 37/28

(52) U.S. Cl. CPC H01J 37/1474; H01J 37/21; H01J 37/222; H01J 37/28; H01J 2237/2801

(57) ABSTRACT

A method of operating a multiple particle beam system can exhibit improved performance. The multiple particle beam system operates with a plurality of first individual charged particle beams. The plurality of first individual particle beams are imaged on an object in a raster arrangement and guided over the object using a collective scan deflector arranged in a crossover region of the first individual particle beams.

### CROSS-REFERENCE TO RELATED APPLICATIONS

The present application is a continuation of, and claims benefit under 35 USC 120 to, international application No. PCT/EP2024/067118, filed Jun. 19, 2024, which claims benefit under 35 USC 119 of German Application No. 10 2023 126 251.3, filed Sep. 23, 2023. The entire disclosure of each of these applications is incorporated by reference herein.

### FIELD

The disclosure relates to multiple particle beam systems which operate using a plurality of individual particle beams.

### BACKGROUND

With the ongoing development of ever smaller and ever more complex microstructures such as semiconductor components, there is a general desire to further develop and optimize planar production techniques and inspection systems for producing and inspecting small dimensions of the microstructures. For example, the development and production of the semiconductor components typically involves monitoring of the design of the wafers, and the planar production techniques involve process monitoring and process optimization for a reliable production with a high throughput. Moreover, there have been recent demands for an analysis of semiconductor wafers for reverse engineering and for a customized, individual configuration of semiconductor components. Therefore, there is a general desire for an inspection mechanism which can be used with high throughput to examine the microstructures on wafers with high accuracy.

Typical silicon wafers used in the production of semiconductor components have diameters of up to 300 mm. Each wafer is divided into 30 to 60 repeating regions (“dies”) with a size of up to 800 mm². A semiconductor apparatus comprises several semiconductor structures, which are produced in layers on a surface of the wafer by planar integration techniques. Semiconductor wafers typically have a plane surface on account of the production processes. The structure sizes of the integrated semiconductor structures in this case extend from a few μm to the critical dimensions (CD) of 5 nm, wherein the structure dimensions will become even smaller in the near future. In the future, structure sizes or critical dimensions (CD) are expected to be below 3 nm, for example 2 nm, or even below 1 nm. In the case of the small structure sizes, it is typically desirable for defects of the size of the critical dimensions to be identified quickly in a very large area. For several applications, the desired accuracy of a measurement provided by inspection equipment is even higher, for example by a factor of two or one order of magnitude. For example, a width of a semiconductor feature is measured with an accuracy of below 1 nm, for example 0.3 nm or even less, and a relative position of semiconductor structures is determined with an overlay accuracy of below 1 nm, for example 0.3 nm or even less.

The MSEM, a multi-beam scanning electron microscope, is a relatively new development in the field of charged particle systems (charged particle microscopes, CPMs). For instance, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. For instance, 4 to 10,000 individual electron beams can be provided as primary radiation, with each individual electron beam being separated from an adjacent individual electron beam by a pitch of 1 to 200 micrometres. For example, an MSEM has approximately J=100 separated individual electron beams (“beamlets”), which for example are arranged in a hexagonal raster, with the individual electron beams being separated by a pitch of approximately 10 μm. The plurality of J individual charged particle beams (primary beams) are focused on a surface of a sample to be examined by way of a common objective lens. For example, the sample can be a semiconductor wafer which is secured to a wafer holder mounted on a movable stage. During the illumination of the wafer surface with the primary individual particle beams, interaction products, e.g. secondary electrons or backscattered electrons, emanate from the surface of the wafer. Their start points correspond to those locations on the sample on which the plurality of J primary individual particle beams are focused in each case. The amount and the energy of the interaction products depend on the material composition and the topography of the wafer surface. The interaction products form several secondary individual particle beams (secondary beams), which are collected by the common objective lens and which are steered to a detector arranged in a detection plane by a projection imaging system of the multi-beam inspection system. The detector comprises several detection regions, each of which comprises several detection pixels, and the detector measures an intensity distribution for each of the J secondary individual particle beams. A digital image of an image field of for example 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the plurality of individual charged particle beams. Such a multi-beam system with charged particles moreover comprises at least one crossover plane of the primary or the secondary individual charged particle beams. Moreover, such a system comprises detection systems in order to facilitate the adjustment. Such a multi-beam particle microscope comprises at least one beam deflector (“deflection scanner”) for collective scanning of a region of the sample surface using the multiplicity of primary individual particle beams in order to completely sweep over the image field of the sample surface with the plurality of the primary beams. Moreover, such a system comprises a beam splitter arrangement which is configured such that the bundle of primary beams is guided from the generating apparatus of the bundle of primary beams to the objective lens, and the bundle of secondary beams is guided from the objective lens to the detection system.

In the case of scanning electron microscopes for wafer inspection, it is desirable to keep the imaging conditions stable such that the imaging can be carried out with relatively great reliability and relatively high repeatability. The throughput depends on several parameters, e.g. the speed of the stage and of the realignment at new measurement sites, and the area measured per unit of capture time. The latter is determined, inter alia, by the dwell time on a pixel, the pixel size and the number of individual particle beams. Additionally, time-consuming image post-processing may be involved for a multi-beam electron microscope; for example, the signal created by the detection system of the multi-beam system with charged particles is digitally corrected before the image field is put together (“stitching”) from several image sub-fields or sub-fields.

Here, the raster positions of the individual particle beams on the sample surface can deviate from the ideal raster position in a plane arrangement. The resolution of the multi-beam electron microscope can be different for each of the individual particle beams and can depend on the individual position of the individual particle beam in the field of individual particle beams, and consequently can depend on the specific raster position of the individual particle beam. A corresponding statement applies to multiple particle beam systems in general.

Generally, conventional systems of multiple charged particle beam systems are stretched to their limits by the increasing demands on resolution and throughput.

One approach for improving precision and resolution lies in the use of a so-called autofocus. Here, while scanning the sample surface, the current focus location of the individual electron beams is ascertained continuously (“on-the-fly”) in view of the sample surface/object plane and an appropriate correction of the focus location is undertaken. For instance, the focus settings of the individual particle beams are adapted for each image field. For instance, this procedure is based on a model of the sample or the assumption that the sample properties do not change much from image field to image field such that prediction values for improved focus settings can be ascertained by extrapolation or interpolation.

WO 2022/069073 A1 discloses a multiple particle beam system with a fast autofocus. In this case, a fast focus correction is performed continuously, with one or more fast autofocus correction lenses being controlled in high-frequency fashion for the autofocus correction. At the same time, other imaging parameters such as the landing angle, the rotation and the magnification can be kept constant during the correction.

Several methods are known that relate to how the location of the best focal plane can be ascertained specifically. The focus location of an individual particle beam is defined by the position of the beam waist of a beam in this case. A best global focus plane is understood to mean the plane in which the focus locations of all the considered individual particle beams are optimized overall. For example, an arithmetic mean can be formed from the individual focal positions (z-positions) of the individual particle beams. However, other mathematical definitions are also possible.

Especially given the development trend towards ever larger image fields and ever more individual particle beams in multiple particle beam systems, it is not only the precise ascertainment of the best global focal plane that is of relevance, but also the individual focal variations of the individual particle beams in relation to the ascertained best global focal plane. In the case of large image fields, the occurrence of field curvature, especially in outer regions of the raster arrangement of individual particle beams, and a corresponding compensation of the field curvature become ever more relevant. For the most part, a deviation of focal positions within the raster that is the result of field curvature (and possibly also field inclination) can be successfully compensated within the raster of individual particle beams. However, an exact compensation is currently not possible in this context. The quality of the focus setting can therefore be read from what is known as a focus map, which for each individual particle beam specifies the individual focus location (z-position) or the deviation from the best global focal plane. Deviations of the individual values from one another, the minimum value and the maximum value allow conclusions to be drawn about the precision of the focus setting. For example, the so-called focus range is a relevant variable for checking the sought-after similarity of the individual particle beams in respect of their beam properties.

For example, applications of multiple particle beam systems are measuring tasks such as e.g. line width measurements (CD measurements) or distance measurements or precision material processing (material ablation or material buildup).

For precision material processing with an individual charged beam such as e.g. an ion beam or an electron beam, it is known that a slight modification/slight detuning of the focus may offer desirable resolution during the material processing. The beam profile changes as a result of the slight modification/slight detuning of the focus, which can be desirable.

Generally, it is not possible to simply transfer this blanket slight detuning from a single beam system to a multiple particle beam system in order to improve imaging properties. A slight detuning of the global focus (in this context, global means to the same extent for the plurality of individual particle beams) sometimes has quite drastic effects in the case of large image fields or in edge regions of a raster arrangement with a plurality of individual particle beams on account of the field curvature which is particularly pronounced there. A defocus of an individual particle beam can easily be up to 1,000 nm there. Moreover, the optimal global focus location—as described above—changes continuously and is adapted, even in the case of very flat objects such as e.g. semiconductor samples with HV structures.

DE 102021200799 B3 has disclosed a method with an improved focus setting taking account of an image plane tilt in a multiple particle beam microscope.

WO 2007/028596 A1 discloses a multiple particle beam system which can be operated in different modes. The different modes differ in terms of the number of individual particle beams focused on a sample. From a structural point of view, an arrangement with several successively arranged multi-aperture plates can moreover be gathered from WO 2007/028596 A1, wherein the centres of the apertures in the first plate are shifted in relation to the centres of the apertures in the second plate.

### SUMMARY

The present disclosure seeks to provide a multiple particle beam system that operates with charged particles and an associated method for operating same with a relatively high throughput, which enables a relatively precise measurement of semiconductor features with a resolution of below 4 nm, below 3 nm or even below 2 nm.

The disclosure seeks to provide a multiple particle beam system which enables relatively highly precise and relatively high-resolution image recording with a relatively high throughput.

The disclosure seeks to provide a multiple particle beam system with an improved resolution.

The disclosure seeks to provide a multiple particle beam system which allows measurement tasks to be performed more precisely.

The disclosure seeks to provide a multiple particle beam system which allows material processing to be implemented more precisely.

The disclosure seeks to improve the beam similarity/beam uniformity of multiple particle beam systems. For example, matching between the individual particle beams can be be improved (“beam-to-beam matching”).

The disclosure includes specific investigations by the inventors that examine the dependence of the location of the global best focal plane both on algorithms used to ascertain the global best focal plane and on parameters which characterize an operating point of a multiple particle beam system. It could be considered that the present disclosure involves two insights:
1. Depending on the algorithm utilized, the investigations by the inventors have demonstrated the existence of differences both in respect of the ascertained individual focal positions of the individual particle beams and in respect of the location (z-position) of the global best focal plane derived therefrom. It may therefore be desirable to ascertain global best focal planes to use algorithms which are specifically adapted to a specific inspection task or work task to be achieved.
2. With regard to the global best focal plane, there is an offset between global best focal positions ascertained using different specifically sensitive algorithms. Wholly surprisingly, it has transpired that this offset depends on the beam current of the individual particle beams or on the overall beam current. This can apply equally to different multiple particle beam systems, and hence in equipment-overarching fashion, provided the multiple particle beam systems have a beam crossover of the individual particle beams in the (optionally first) particle-optical beam path. It is suspected that the Coulomb interaction between the individual charged particle beams in the beam crossover is the cause for this relationship between global focus offset on the one hand and beam current on the other hand. However, the discovered effect has practical applications, even without detailed theoretical interpretation.

According to a first aspect, the disclosure provides to a method for operating a multiple particle beam system with improved performance, the multiple particle beam system operating with a plurality of first individual charged particle beams, the plurality of first individual particle beams being imaged on an object in a raster arrangement and being guided over the object using a collective scan deflector arranged in a crossover region of the first individual particle beams, and the method including the following steps: defining a first operating point A_1 of the multiple particle beam system comprising a first beam current I_1; ascertaining a first global focusing Fg_1, by which the plurality of first individual particle beams can be imaged on the object at the first operating point A_1; ascertaining a best first global offset d_1 from the best first global focusing Fg_1 on the basis of the first beam current I_1; ascertaining a first global detuned focusing F_detune_1 on the basis of the first global offset d_1; and raster scanning the object with the plurality of first individual particle beams at the first operating point A_1 with the first global detuned focusing F_detune_1 for a performance increase.

The charged particles which form the first individual charged particle beams can be e.g. electrons, positrons, muons or ions or other charged particles. These can be electrons generated e.g. using a thermal field emission source (TFE). However, other particle sources can also be used.

In general, the number of first individual particle beams can be chosen variably. However, it can be desirable for the number of particle beams to be 3n(n−1)+1, where n is any natural number. This can permit a hexagonal raster arrangement of the plurality of first individual charged particle beams. Other raster arrangements, e.g. in a square or rectangular raster, are likewise possible. For example, the number of first individual particle beams is more than 5, more than 60 or more than 100 individual particle beams. In the execution of the method for operating the multiple particle beam system, the multiple particle beam system can be operated with all available first individual charged particle beams; however, it can also be operated with only a selection of the first individual charged particle beams.

The object to be raster scanned or scanned can be of any desired type, for example a semiconductor wafer, such as a semiconductor wafer with HV structures (i.e. with horizontal and/or vertical structures), or a biological sample, or the object can comprise an arrangement of miniaturized elements or the like.

The operating point A_1 of the multiple particle beam system can comprise at least one parameter, specifically a first beam current I_1. However, the operating point A_1 can also comprise further parameters, for example the landing energy or imaging parameters such as the magnification, the telecentricity, etc. Defining the first operating point A_1 implicitly also contains the definition of a working distance WD_1, which describes the location of the object or its surface in relation to the imaging particle-optical system, for example as a distance from the particle-optical centre of an objective lens. The first beam current I_1 can be specified as overall beam current or else as beam current of the respective individual particle beams.

A further method step includes ascertaining a best first global focusing Fg_1, by which the plurality of first individual particle beams can be imaged on the object at the first operating point A_1. Thus, actually implementing this imaging with the best first global focusing Fg_1 is not required. For example, it is possible that the best first global focusing Fg_1 is already known in advance or has been ascertained in advance and is read into a controller of the multiple particle beam system, for example from a lookup table or from a database. In the case of the best first global focusing Fg_1, there is focused imaging on the object or its surface. There is an individual best focus location for each of the first individual particle beams; for example, this may be defined by way of the site of the minimal beam waist. The best first global focusing Fg_1 can be ascertained from the ensemble or totality of best focus locations of the individual particle beams. There are several options to this end. They will be described in detail below. For the purpose of the described method for operating a multiple particle beam system with improved performance, what can be decisive is that this best first global focusing Fg_1 initially exists, or has possibly been ascertained in advance, for this first operating point A_1 and hence for the working distance WD_1 specified by the operating point A_1 and the associated first beam current I_1.

A further method step includes ascertainment of a first global offset d_1 from the best first global focusing Fg_1 on the basis of the first beam current I_1. Thus, the best first global focusing Fg_1 might not be the most suitable focusing for the specific work task or measurement task. Instead, the first global focusing is still detuned for an application-related best global focusing. The degree of detuning involved can be specified in this case by what is known as the first global offset d_1. Here, the magnitude of this first global offset d_1 can depend on the first beam current I_1. In other words, the first global offset d_1 can be based or dependent on the first beam current I_1. Once again, the first global offset d_1 can be ascertained in advance, and the first global offset d_1 associated with the first beam current I_1 (for a given working distance WD_1) only is to still be read or entered within the scope of the ascertainment.

A further method step includes ascertaining a first global detuned focusing F_detune_1 on the basis of the first global offset d_1. For example, it is possible that the first global offset d_1 exactly describes the difference between the best first global focusing Fg_1 and the first global detuned focusing F_detune_1. However, it is also possible that there is a further correction or a further offset between the first global focusing Fg_1 and the first global detuned focusing F_detune_1. In any case, however, the first global detuned focusing F_detune_1 can be based on the first global offset d_1. The fact that an ascertainment may have already been implemented in advance, which has already been mentioned multiple times above, applies in respect of this ascertainment; it need not be implemented during the course of carrying out the method itself.

A further method step includes raster scanning of the object with the plurality of first individual particle beams at the first operating point A_1 with the first global detuned focusing F_detune_1 for a performance increase. The first global detuned focusing F_detune_1 can be a best or optimized first global detuned focusing F_detune_1. In this case, it is possible that the object is raster scanned in full or only in part. In this patent application, the term “raster scanning” should be understood to be synonymous with the term “scanning”. It is not necessary for an object to be raster scanned comprehensively or for a few regions of the object to be raster scanned comprehensively; it is sufficient for only selected sites on the object to be scanned with the plurality of first individual particle beams.

The first global detuned focusing F_detune_1 can be the better focusing for the imaging process and its underlying task when compared to the best first global focusing Fg_1, i.e. it exhibits the better resolution result (with the definition of resolution once again depending on the specific task and the considered variables).

Summarized briefly, raster scanning according to the disclosure of the object with the plurality of first individual particle beams is not implemented with the best first global focusing Fg_1 optionally ascertained in advance. Instead, it is implemented with a first global detuned focusing F_detune_1, with the two global focusings substantially differing from one another by the offset d_1. Better inspection results or work results can be obtained on account of the global detuning of the focusing.

According to an embodiment of the disclosure, the method furthermore includes the following steps: selecting an inspection task or work task; and ascertaining the first global offset d_1 on the basis of the selected inspection task or work task. It is possible that values for the offset d_1 at a specific beam current I_1 have already been determined in advance for different inspection tasks or work tasks before the raster scan process itself is carried out. Specific algorithms which are particularly sensitive to the inspection task or work task can be correspondingly used when determining the first global offset d_1.

According to an embodiment of the disclosure, the inspection task is a dimension measurement, for example a line width measurement or resolution measurement. According to an embodiment of the disclosure, the work task is a material ablation, such as microprocessing using ions, or a material buildup, for example using the use of electron beams. However, other inspection tasks and/or work tasks are also possible.

According to an embodiment of the disclosure, the method moreover includes the following steps: ascertaining actual autofocus data when raster scanning the object; and dynamically correcting the best first global focusing Fg_1 on the basis of the actual autofocus data; and dynamically varying the first global detuned focusing F_detune_1 on the basis of the dynamic correction of the best first global optimal focusing Fg_1.

According to this embodiment of the disclosure, it is possible to integrate the improved or detuned global focusing into an existing autofocus process. The first two additional method steps, a feedback loop, are already known from the prior art. This is now supplemented by the dynamic variation of the first global detuned focusing F_detune_1 on the basis of the dynamic correction of the best first global focusing Fg_1. Scanning or raster scanning is only implemented with the first global detuned focusing F_detune_1 in this case. Details with regard to a fast autofocus can be gathered from the international patent application WO 2022/069073 A1, for example, the disclosure of which is fully integrated into the present patent application by reference.

According to an embodiment of the disclosure, the method moreover includes the following steps: defining a second operating point A_2 of the multiple particle beam system comprising a second beam current I_2; ascertaining a best second global focusing Fg_2, by which the plurality of first individual particle beams can be imaged on the object at the second operating point A_2; ascertaining a second global offset d_2 from the best second global focusing Fg_2 on the basis of the second beam current I_2; determining a second global detuned focusing F_detune_2 on the basis of the second global offset d_2; and raster scanning the object with the plurality of first individual particle beams at the second operating point A_2 with the second global detuned focusing F_detune_2 for a performance increase.

This embodiment variant of the disclosure thus can describe aspects of a change from an operating point A_1 to a second operating point A_2. In a simple case, the second operating point A_2 only differs from the first operating point A_1 in terms of a different beam current, i.e. I_1≠I_2. All remaining parameters, and for example the working distance WD, can remain unchanged. If the beam current is now changed from I_1 to I_2, then there is also a change in the global offset d_2, dependent thereon, and hence also in the second global detuned focusing F_detune_2. In other words, what holds true is that, in comparison with performing the method at the first operating point A_1, the object is raster scanned or scanned firstly with a different beam current, specifically I_2, and secondly with a different global detuned focusing F_detune_2 for a performance increase. Otherwise, the statements also already made in the context of the first operating point A_1 apply analogously to the individual aspects of this embodiment.

According to an embodiment of the disclosure, the method moreover includes the following steps: ascertaining actual autofocus data when raster scanning the object at the second operating point A_2; and dynamically correcting the second global optimal focusing Fg_2 on the basis of the actual autofocus data; and dynamically varying the second global detuned focusing F_detune_2 on the basis of the dynamic correction of the second global focusing Fg_2.

Thus, the method according to the disclosure can be integrated into an autofocus at the second operating point A_2, too. With regard to the autofocus aspect, what was stated in conjunction with the autofocus at the first operating point A_1 applies in turn.

According to an embodiment of the disclosure, the method furthermore includes the following step: correcting a telecentricity error at an operating point A_i on the basis of the ascertained associated global offset d_i.

The operating point A_i can be the first operating point A_1 or the second operating point A_2 or a further operating point A_i. The telecentricity error to be corrected is a telecentricity error that may but need not occur on account of the detuned focusing on the basis of the offset d_i. By definition, the telecentricity error is not present or corrected by already existent correction systems and mechanisms when raster scanning the object with a global optimal focusing Fg. To correct the telecentricity error additionally arising due to the detuning, it is possible to use the same telecentricity correction mechanism that is used to ensure the best global optimal focusing; however, other telecentricity correction mechanisms can also be used. The telecentricity correction according to this embodiment variant can be a static telecentricity correction and can be corrected, for example, by a modified focal length setting of the condenser lenses in a multiple particle beam system or by a deflector array in an intermediate image plane of the multiple particle beam system.

According to an embodiment of the disclosure, an operating point A_i is defined by at least one further parameter, such as by a working distance and/or by a landing energy, and the ascertainment of a global offset D_i of the associated global focusing Fg_i is implemented on the basis of at least one of these further parameters.

The embodiments according to the first aspect of the disclosure can be combined with one another in full or in part, provided that no technical contradictions arise as a result.

In the description of the first aspect of the disclosure, attention was drawn to the fact that the best first global focusing Fg_1, the first global offset d_i and the first global detuned focusing F_detune_1 may have been ascertained in advance. A calibration method for ascertaining the first global offset d_1, on which the first global detuned focusing F_detune_1 is based, is described below:

According to an aspect, the disclosure provides a calibration method for a multiple particle beam system operating with a plurality N of first individual charged particle beams, the plurality N of first individual particle beams being arranged in a first raster arrangement and being imaged on an object at incidence locations, which form a second raster arrangement, and being guided over the object using a collective scan deflector, which is arranged in a crossover region of the first individual particle beams, with second individual particle beams emanating from the incidence locations of the object being detected in each case by a detection system comprising a particle multi-detector and with the multiple particle beam system comprising a data capture and data processing unit, the method including the following steps:
a) setting a first operating point A_1 of the multiple particle beam system with a first beam current I_1;
b) at the first operating point A_1, recording a focus series of a reference object using the plurality of first individual particle beams and creating and storing digital images of the focus series using the detection system and the data capture and data processing unit;
c) analysing the digital images and ascertaining a best global focus location Fg_11 using a first algorithm;
d) analysing the digital images and ascertaining a further best global focus location Fg_12 using a second algorithm;
e) determining an offset d_1 between the focus location Fg_11 and the focus location Fg_12;
f) storing the offset d_1 in the data capture and processing unit in relation to the first beam current I_1.

Various methods for recording a focus series of an object or reference object and various methods for evaluating the image series ascertained thereby are already known from the prior art. DE 10 2021 200 799 B3 discloses various methods for an improved focusing, which can also take account of field inclination in addition to field curvature. The disclosure of DE 10 2021 200 799 B3 is fully incorporated in the present patent application by reference. The described method for ascertaining a global focus location or optimal focal plane is based on the capture of contrast measures in different focus or Z-positions. A method for determining a contrast measure can be e.g. one of the following methods: a spectral method, an image contrast, a histogram method, an edge filter, a method of relative spread or blur, or a gradient method. In this case, different methods can also be combined with one another.

In very general terms, it is the case that many autofocus methods use image sharpness algorithms (e.g. CNR or NIS) to ascertain the optimal focusing. These image sharpness-based algorithms were examined by the inventors in detail, and it transpired that these image sharpness algorithms in fact ascertain the positions of a minimal beam waist of the individual particle beams very precisely and comprehensibly, whereby in turn, overall, a best global focus location can be ascertained by different mathematical methods.

However, in addition to the aforementioned image sharpness algorithms, there are also other algorithms, based on other criteria, for finding a best “focus position”. In this context, a contrast gradient method is a relevant method. While image sharpness methods direct their optimization to positions with minimal beam waist (“circle of least confusion”), contrast gradient methods optimize the Gauss plane (“Gauss optimum”). Thus, depending on the algorithm utilized, a respective difference arises when analysing the same digital images and when ascertaining the best global focus location: The best first global focus location Fg_11 created using a first algorithm differs from the further best global focus location Fg_12 created using a second algorithm. The two focus locations Fg_11 and Fg_12 differ by the offset d_1. This offset d_1 can then be stored in the data capture and processing unit in relation to the first beam current I_1. The best first global focusing Fg_11 can in this case correspond to the best first global focus location Fg_1 and the further best global focus location Fg_12 can in this case correspond to the first global detuned focus location F_detune_1, which have been defined and described in the context of the first aspect of the disclosure.

The described calibration method can be performed analogously for the second beam current I_2 and/or further beam currents I_i.

According to an embodiment of the disclosure, the calibration method furthermore comprises the following steps:
g) setting a second operating point A_2 of the multiple particle beam system with a second beam current I_2;
h) at the second operating point A_2, recording a focus series of a reference object using the plurality of first individual particle beams and creating and storing digital images of the focus series using the detection system and the data capture and data processing unit;
i) analysing the digital images and ascertaining a best global focus location Fg_21 using the first algorithm;
j) analysing the digital images and ascertaining a further global focus location Fg_22 using the second algorithm;
k) determining an offset d_2 between the best global focus location Fg_21 and the further best global focus location Fg_22;
l) storing the offset d_2 in the data capture and processing unit in relation to the second beam current I_2.

According to an embodiment of the disclosure, method steps a) to f) are carried out for a further operating point A_i or for several further operating points A_i. Optionally, the working distance WD_i is initially kept constant for the further operating points A_i. However, it is naturally also possible to perform method steps a) to f) for further operating points A_i with a modified working distance WD′ as well. Other parameters characterizing an operating point A_i, for example the landing energy, the magnification, the beam spacing or pitch, can also be captured and selectively kept constant or varied, and their influence on the offset-in addition to the influence of the beam current during the calibration-can be captured.

According to an embodiment of the disclosure, the first algorithm is configured to ascertain the focus location of the first individual particle beams as positions with minimal beam waist. In addition to that or in an alternative, the second algorithm is configured to ascertain the focus location of the first individual particle beams as positions of the Gauss plane of the beam trajectories.

According to an embodiment of the disclosure, the first algorithm operates on the basis of an image sharpness criterion and the second algorithm operates on the basis of a contrast gradient method.

According to an embodiment of the disclosure, a best global focus Fg_i at an operating point A_i for a plurality M≤N of the first individual particle beams with in each case an individual best focus f_j, where j=1, . . . , M, is ascertained as an arithmetic mean of the individual foci f_j. The conclusion regarding the best global focus Fg_i from the individual foci f_j can be identical when ascertaining the global focus location Fg_i1 and the further global focus location Fg_i2. This increases the meaningfulness of the ascertained offset d_i between the global focus locations Fg_i1 and Fg_i2.

According to an embodiment of the disclosure, the maximum defocus of individual particle beams is minimized for the purpose of ascertaining the best global focus location. To this end, a best global focus Fg_i at an operating point A_i for a plurality M≤N of the first individual particle beams with in each case an individual best focus f_j, where j=1, . . . , M, is formed as an arithmetic mean of the maximum individual focus f_max and the minimum individual focus f_min.

Naturally, it is possible to form the best global focus Fg_i on the basis of focus locations of all individual particle beams, i.e. on the basis of N beams. However, it is also possible to consider only a subgroup with M first individual particle beams for the purpose of ascertaining the global focus. Such methods might be faster but are not necessarily more accurate. The position of the best global focus Fg_i can depend on the number of individual particle beams used.

According to an aspect, the disclosure provides a computer program product having a program code for carrying out the method for operating a multiple particle beam system with improved performance and/or for carrying out the calibration method. In this case, the program code can be written in any desired programming language. It can comprise one module or several modules. The program code can be loaded into a controller of a multiple particle beam system in order to control the multiple particle beam system according to the described methods.

According to an aspect, the disclosure provides a multiple particle beam system configured to carry out the method for operating the multiple particle beam system with improved performance and/or the calibration method for a multiple particle beam system. The multiple particle beam system can be an inspection system or a lithography system or a microprocessing system or any other multiple particle beam system.

According to an aspect, the disclosure provides a multiple particle beam system for wafer inspection, comprising the following: a multi-beam particle generator, which is configured to create a first field of a plurality of first individual charged particle beams; a first particle-optical unit with a first particle-optical beam path, configured to image the created first individual particle beams on a wafer surface in the object plane such that the first individual particle beams are incident on the wafer surface at incidence locations which form a second field;
a detection system having a plurality of detection regions which form a third field; a second particle-optical unit with a second particle-optical beam path, configured to image second individual particle beams, which emanate from the incidence locations in the second field, on the third field of the detection regions of the detection system; a magnetic and/or electrostatic objective lens, through which both the first and the second individual particle beams pass; a beam splitter, which is arranged in the first particle-optical beam path between the multi-beam particle generator and the objective lens and which is arranged in the second particle-optical beam path between the objective lens and the detection system; a crossover region of the first individual charged particle beams in the first particle-optical beam path, with a collective first scan deflector for collectively scanning the first individual charged particle beams over the object being arranged in the region of the crossover region; a sample stage for holding and/or positioning a wafer during the wafer inspection; an autofocus measuring element, which is configured to create measurement data for ascertaining actual autofocus data during the wafer inspection; at least one fast autofocus correction lens; and
a controller having a data processing and storage unit; an autofocus correction mode selection device for selecting a first autofocus correction mode which is beam current-independent in view of an autofocus correction and for selecting a second autofocus correction mode which is beam current-dependent in view of the autofocus correction;
wherein the controller is configured to control particle-optical components in the first and/or in the second particle-optical beam path, wherein the controller is configured for static or low-frequency adaptation of a focusing in order to control at least the objective lens and/or an actuator of the sample stage at an operating point A_i with a beam current I_i and a working distance WD_i in such a way that the first individual particle beams are focused on the wafer surface situated at the working distance WD_i, and wherein the controller is configured for high-frequency adaptation of the focusing in the first autofocus correction mode, in order to create an autofocus correction lens control signal on the basis of the actual autofocus data at the operating point A_i during the wafer inspection in order to control the at least one fast autofocus correction lens in high-frequency fashion during the wafer inspection at the operating point A_i, wherein the controller is configured for high-frequency adaptation of the focusing in the second autofocus correction mode, in order to create an autofocus correction lens control signal on the basis of the actual autofocus data and on the basis of the beam current I_i at the operating point A_i during the wafer inspection in order to control the at least one fast autofocus correction lens in high-frequency fashion during the wafer inspection at the operating point A_i and/or in order to control the objective lens in static or low-frequency fashion during the wafer inspection at the operating point A_i, in such a way that the first individual particle beams are focused in detuned fashion on the wafer surface situated at the working distance WD_i.

According to this embodiment variant of the disclosure, an autofocus correction in a multiple particle beam system for wafer inspection can thus be beam current-dependent and comprise targeted detuning of the focusing. Whether or not this beam current dependence and detuning is desirable depends firstly on a specific inspection task and secondly on the algorithms used to deduce the current focus location. The statements made in the context of the other aspects of the disclosure also apply accordingly to the fifth aspect.

The second autofocus correction mode is beam current-dependent in respect of the autofocus correction. This means that the autofocus correction performed in this mode comprises a beam current-dependent portion or beam current-dependent detuning, i.e. the detuning dependent thereon. Specifically, the described autofocus correction comprises a component on account of the modified focus location due to the topography of the object and a component on account of the beam current. The topography-dependent component is corrected virtually instantaneously and hence in high-frequency fashion, which is why this is implemented by an appropriate control of the at least one fast autofocus correction lens. The situation is different for the correction of the beam current-dependent component: The beam current-dependent correction is substantially an offset, as has been described in detail above in the context of the first to fourth aspects of the disclosure. On the one hand, this offset can likewise be taken into account by an appropriate control of the at least one fast autofocus correction lens. In addition to that or in an alternative, it is however also possible to correct this beam current-dependent component by a static or low-frequency control of the objective lens. Which embodiment variant is more desirable depends on, for example, the size of the offset d_1 which arises on account of the beam current dependence. If this offset d_1 is of the same order of magnitude as the corrections involved on account of the topography of the object, then this correction can be implemented well by controlling the at least one fast autofocus correction lens. However, if the offset is comparatively large, there can be (also) a static or low-frequency correction using a modified control of the objective lens.

According to an embodiment of the disclosure, the magnitude of a respectively associated offset d_i is stored in the data processing and storage unit for a plurality of operating points A_i with an associated beam current I_i, wherein the at least one autofocus correction lens control signal is varied on the basis of the stored offset d_i in the second autofocus correction mode.

According to an embodiment of the disclosure, the controller is furthermore configured to likewise keep the landing angle and the raster arrangement of the first individual particle beams upon incidence on the wafer substantially constant during the high-frequency adaptation of the focusing. This keeping constant for the beam current-independent fast autofocus correction is already known from WO 2022/069073 A1, which has been cited several times.

According to an embodiment of the disclosure, the multiple particle beam system moreover comprises a telecentricity correction mechanism, wherein the controller of the multiple particle beam system is configured to control the telecentricity correction mechanism in the second autofocus correction mode using a telecentricity correction mechanism control signal based on the beam current I_i. Optionally, the telecentricity correction mechanism is controlled in low-frequency or static fashion since the telecentricity error basically is an offset error. In this case, particle-optical components of the first particle-optical beam path, present in the multiple particle beam system in any case, can be used as telecentricity correction mechanism. For example, a focal length of the condenser lens system can be modified for the telecentricity correction, or it is possible, in addition to that or in an alternative, to arrange a deflector array in the intermediate image plane of the multiple particle beam system. In addition to one alternative, it is however also possible to carry out a telecentricity correction in high-frequency fashion.

In summary, it is possible for an object or a wafer surface to be raster scanned or scanned in a relatively high-frequency fashion with a slightly detuned focusing in this embodiment variant as well, since this can lead to improved performance for certain inspection tasks.

The various embodiment variants of the disclosure according to the aspects of the disclosure can be combined with one another in full or in part, provided that no technical contradictions arise as a result.

The disclosure will be understood even better with reference to the accompanying figures.

### BRIEF DESCRIPTION OF THE DRAWINGS

In the figures:

FIG. 1: schematically shows a multiple particle beam system using the example of a multi-beam particle microscope;

FIG. 2: schematically shows an influence of an image plane displacement on the beam profile;

FIG. 3: shows an offset between best global foci which were ascertained using different algorithms;

FIG. 4: shows measurements of an offset on the basis of the beam current in different multiple particle beam systems;

FIG. 5: schematically illustrates properties of a best global focus position;

FIG. 6: shows a flowchart of a method for operating a multiple particle beam system with improved performance; and

FIG. 7: shows a flowchart of a calibration method for a multiple particle beam system.

### DETAILED DESCRIPTION

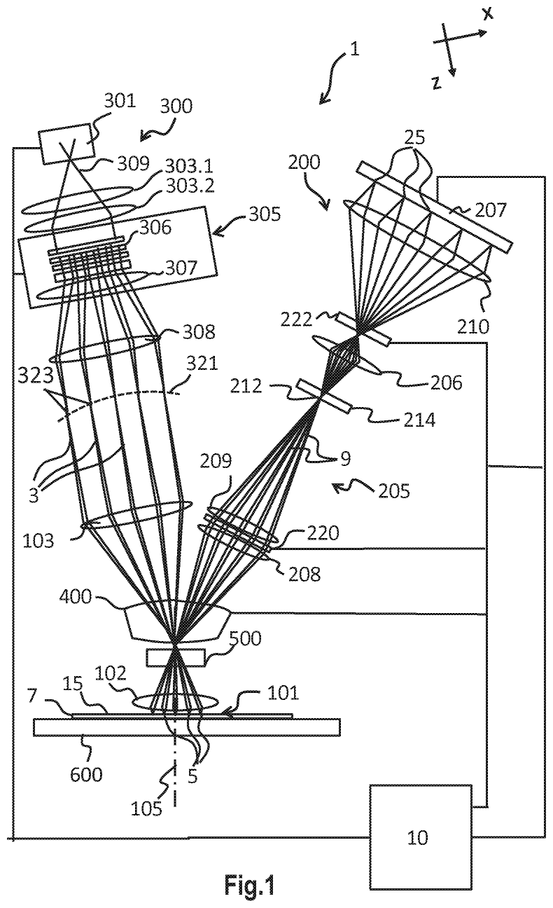

FIG. 1 schematically shows a multiple particle beam system using the example of a multi-beam particle microscope 1. The multi-beam particle microscope 1 comprises a beam generating apparatus 300 with a particle source 301, for instance an electron source. A divergent particle beam 309 is collimated by a sequence of condenser lenses 303.1 and 303.2 and incident on a multi-aperture arrangement 305. The multi-aperture arrangement 305 comprises a plurality of multi-aperture plates 306 and a field lens 308. A plurality of individual particle beams 3 or individual electron beams 3 are generated by the multi-aperture arrangement 305. Midpoints of apertures in the multi-aperture plate arrangement are arranged in a field which is imaged on a further field formed by beam spots 5 in the object plane 101. The pitch between the midpoints of apertures of a multi-aperture plate 306 can be for instance 5 μm, 100 μm and 200 μm. The diameters D of the apertures are smaller than the pitch of the midpoints of the apertures; examples of the diameters are 0.2 times, 0.4 times and 0.8 times the pitch between the midpoints of the apertures.

The multi-aperture arrangement 305 and the field lens 308 are configured to generate a multiplicity of focal points 323 of primary beams 3 in a raster arrangement on a surface 321. The surface 321 need not be a plane surface but rather can be a spherically curved surface in order to account for a field curvature of the subsequent particle-optical system.

The multi-beam particle microscope 1 further comprises a system of electromagnetic lenses 103 and an objective lens 102, which image the beam foci 323 from the intermediate image surface 325 in the object plane 101 with reduced size. In between, the first individual particle beams 3 pass through the beam splitter 400 and a collective beam deflection system 500, by which the plurality of the first individual particle beams 3 are deflected during operation and the image field is scanned. The first individual particle beams 3 incident in the object plane 101 for example form a substantially regular field, wherein the pitch between adjacent incidence locations 5 can be 1 μm, 10 μm or 40 μm, for example. For instance, the field formed by the incidence locations 5 can have a rectangular or hexagonal symmetry.

The object 7 to be examined can be of any desired type, for instance a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. For instance, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 μm, 100 μm and 200 μm.

The multi-beam particle microscope 1 further comprises a computer system or a control unit 10, which in turn can have a single-part or multi-part design and which is designed both to control the individual particle-optical components of the multi-beam particle microscope 1 and to evaluate and analyse the signals obtained by the multi-detector 207 or the detection unit.

Further information relating to such multi-beam particle beam systems or multi-beam particle microscopes 1 and component parts used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated in the present application by reference.

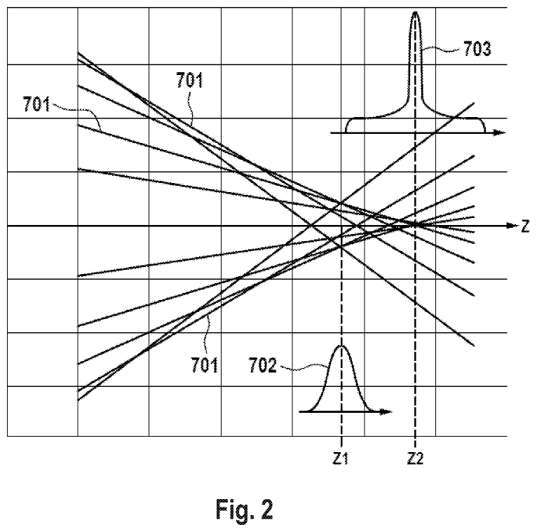

FIG. 2 schematically shows the influence of an image plane displacement on the beam profile of a charged particle beam. FIG. 2 illustrates some trajectories 701 of charged particles by way of example. The direction of propagation of the particle beam is along the particle-optical axis Z, with the beam being focused at a position Z1. Specifically, this focusing at the position Z1 means that the beam waist of the particle beam is minimal at the position Z1. The charged particle beam has the profile 702 at the position Z1. In the example shown, the beam profile 702 is bell shaped. If the image plane is displaced into position Z2, then there is a change in the beam profile: in comparison with the beam profile 702, the beam profile 703 has a tighter and more peaked maximum but, at the same time, also a flat, broader shoulder. Both beam profiles 702 and 703 are optimal beam profiles; however, they differ in terms of the parameter in respect of which the optimization is carried out.

Normally, when the prior art refers to a best focus location or focusing, then this normally means the beam profile 702 with the minimized beam waist. The location of this minimal beam waist at the position Z1 can be ascertained, for example, on account of focus series with subsequent image evaluation of the digital image data obtained in the process. In this case, the optimization parameter can be the image sharpness, for example.

Something else happens in the case of an optimization with respect to the Gaussian optimum or beam profile 703: for example, a contrast gradient is a parameter to be optimized.

From single beam systems, it is known that, depending on a specific inspection task or work task, the best focus location Z1 need not be the focus location that supplies the best inspection result or work result. Instead, it is known that better results can be obtained using a slightly detuned focus. In the case of single beam systems, this can be explained by the fact that a beam profile 703 or the Gaussian optimum for the beam profile can be desirable over the bell-shaped profile.

Even if considerations regarding the best focus location in a single beam system cannot simply be transferred to a multiple particle beam system, the statement that the beam profile of a bundle of rays also changes depending on the image plane location is nevertheless correct. Naturally, this change may have an influence on the performance of work tasks or inspection tasks.

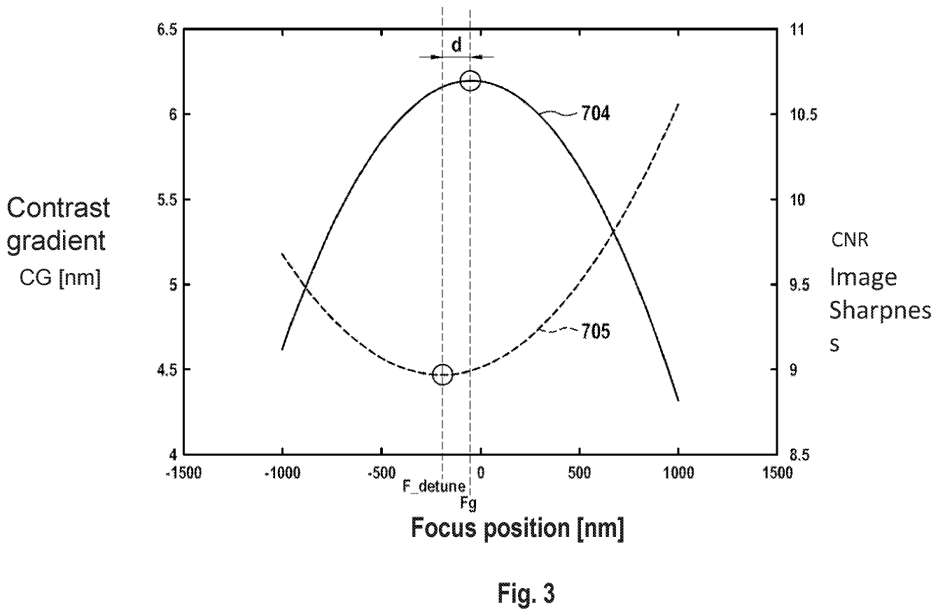

FIG. 3 shows an offset between best global foci of a multiple particle beam system, wherein the two best global foci were ascertained using different algorithms. A focus position in nanometres is depicted along the x-axis. A contrast gradient in nanometres (CG) is plotted on the left y-axis. An image sharpness (CNR value) is plotted on the right y-axis. The curve of the image sharpness 704 exhibits a global maximum at the focus position Fg. By contrast, the curve 705 of the contrast gradient exhibits a minimum at the position F_detune. An offset d is situated between these two global positions Fg and F_detune. In the depicted example, this offset d is approximately 200 nanometres.

If a multiple particle beam system 1 should now implement a specific measurement task, for example a length measurement or a line width measurement, then the result of this length measurement depends substantially on two factors: the signal-to-noise ratio on the one hand and the resolution of the utilized particle beam on the other. The signal-to-noise ratio is linked to the image sharpness while the resolution of the beam is linked to the value of the contrast gradient, for example. The curve of the image sharpness 704 has a different optimum to the curve of the contrast gradient 705, with a line width measurement at the same time being more sensitive to the value of the contrast gradient. In general terms, different image evaluation algorithms for ascertaining an extremal value may be sensitive to different image content. Therefore, the multiple particle beam system may have a better performance if it operates not with the global focus Fg but with the global detuned focus F_detune.

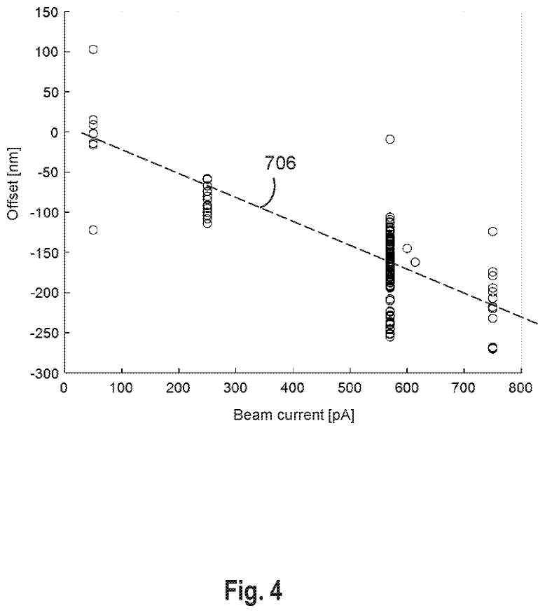

As already mentioned, it has transpired over the course of the investigations by the inventors that there is an offset between two global best focus positions as ascertained by different specifically sensitive algorithms, this offset depending on the beam current of the individual particle beams or on the overall beam current. FIG. 4 shows corresponding measurements of an offset on the basis of the beam current in different multiple particle beam systems. The beam current in pA is plotted along the x-axis; the offset between the two best focus positions is plotted along the y axis. Specifically, FIG. 4 plots the global offset between the best global focus position in a contrast gradient method and the best global focus position as ascertained on the basis of an image sharpness algorithm (CG-CNR offset). The discovered relationship between the offset d and the beam current I is linear, as depicted by curve 706 in FIG. 4.

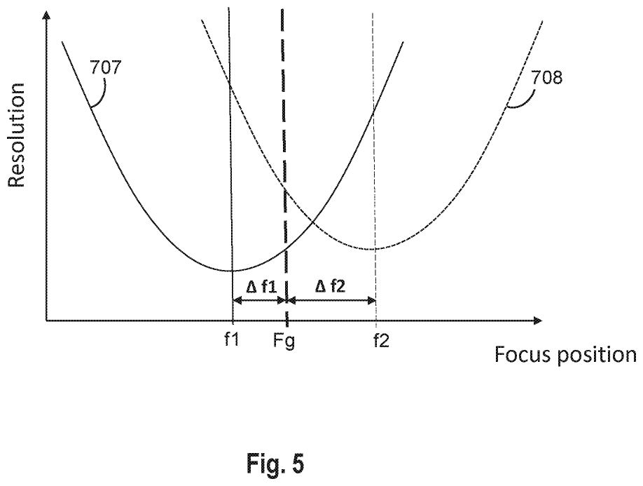

FIG. 5 schematically illustrates properties of a best global focus position. The explanations given below are independent of the algorithm used in each case, on the basis of which the optimal focus position was ascertained. Each individual particle beam 3 has an individual best focus position or an individual defocus. In FIG. 5, this is depicted by way of example for two individual particle beams: curve 707 shows the resolution of a first individual particle beam and curve 708 shows the resolution of a second individual particle beam. The optimal individual focus f1 of the first curve is plotted in FIG. 5. It corresponds to the location with the minimal resolution. Accordingly, the individual best focus f2 is depicted in FIG. 5 as minimum of curve 708. Moreover, FIG. 5 plots an optimal global focus Fg, in relation to which the two individual particle beams each have an individual defocus Δf1 and Δf2. In order to ascertain a best global focus from a plurality of individual best focus positions f_j, where j=1, . . . , M, it is possible, on the one hand, to form an arithmetic mean of the individual foci f_j. However, in the case of a large image field or a large number of individual particle beams in a raster, this may lead to a defocus being very large, especially in the edge regions of the raster. For this reason, it may be desirable to ascertain a global focus Fg for a plurality M≤N of the first individual particle beams with in each case an individual best focus f_j, where j=1, . . . , M, differently, to be precise as an arithmetic mean of the maximum individual focus f_max on the one hand and the minimum individual focus f_min on the other. This procedure leads to there being a control over the maximum defocus or a minimization of the maximally occurring defocus of an individual particle beam. This may be desirable in view of the matching between individual particle beams (improved “beam-to-beam matching”).

What also is to be taken into account is that the ascertainment of the global focus Fg depends on whether the global focus is ascertained for all N first individual particle beams or for a selection M of the first individual particle beams, with M≤N. It is recommended within the scope of a calibration method to use the entire plurality N of individual particle beams for the ascertainment of the best global focus positions.

The method according to the disclosure leads to significantly better results, for example in the case of line width measurements. If e.g. 60 nm wide lines of a semiconductor sample are measured using the plurality of individual particle beams for calibration purposes, then the result of the measurement should be the same for each first individual particle beam when the same structure is measured. In that case, possible variations in the ascertained values are not caused by varying line widths, for example, but purely by the measuring instrument. The variation in the line width measurements, the so-called CD range, can be reduced for example from 2.58 nm to 1.70 nm by the method according to the disclosure. The corresponding contrast gradient range (CG range) is also reduced significantly, specifically from 1.13 nm to 0.73 nm in one example.

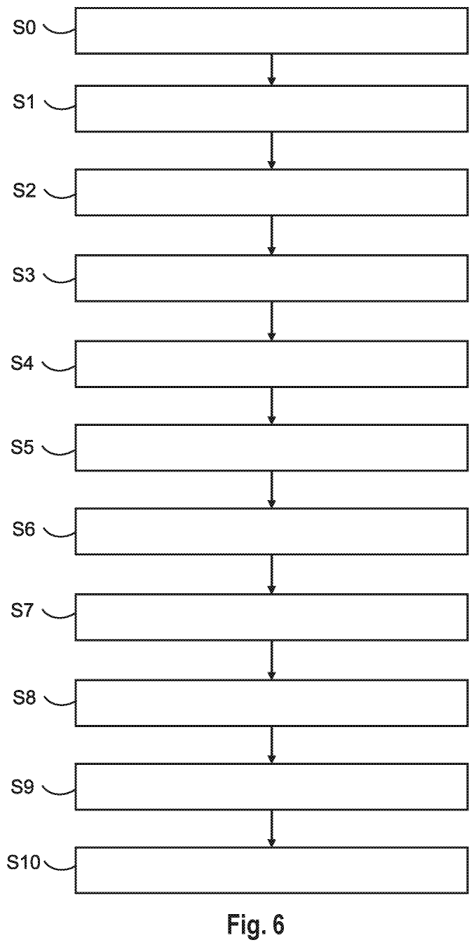

FIG. 6 shows a flowchart of a method according to the disclosure for operating a multiple particle beam system 1 with improved performance. The multiple particle beam system 1 is provided in an initial method step S0. This multiple particle beam system operates with a plurality of first individual charged particle beams 3, wherein the plurality of first individual particle beams 3 are imaged on an object 7 in a raster arrangement and guided over the object 7 using a collective scan deflector 500 arranged in a crossover region of the first individual particle beams 3.

A first operating point A_1 of the multiple particle beam system 1 comprising a first beam current I_1 is defined in a first method step S1. In this case, the operating point A_1 can also be defined by a further parameter, for example by a working distance WD or by a landing energy.

In a method step S2 there is the ascertainment of a best first global focusing Fg_1, by which the plurality of first individual particle beams 3 can be imaged on the object 7 at the first operating point A_1. The ascertainment of the best first global focusing Fg_1 can already have been implemented in advance in this case, e.g. using calibration; it need not be implemented only once the method is performed.

In a further method step S3 there is the ascertainment of a first global offset d_1 from the first global focusing Fg_1 on the basis of the first beam current I_1. The first global offset d_1 can likewise have already been ascertained in advance, e.g. by way of a calibration.

In a further method step S4 there is the ascertainment of a first global detuned focusing F_detune_1 on the basis of the first global offset d_1. In this case, the ascertainment of the first global detuned focusing F_detune_1 may likewise have already been implemented in advance, e.g. during a calibration, and need not be implemented only once the specific method is performed.

In a further method step S5 there is the raster scanning of the object 7 with the plurality of first individual particle beams 3 at the first operating point A_1 with the first global detuned focusing F_detune_1 for a performance increase. In this case, the raster scanning of the object 7 can be a complete or partial raster scan. In the sense of this patent application, the term raster scanning is used synonymously with the term scanning.

A second operating point A_2 of the multiple particle beam system comprising a second beam current I_2 is defined in a further method step S6 in the exemplary embodiment described. In this case, the first beam current I_1 differs from the second beam current I_2. Moreover, it is the case in the described exemplary embodiment that the remaining parameters which may characterize the second operating point A_2 remain unchanged. Thus, the beam current I is the only parameter varied.

In a further method step S7 there is the ascertainment of a best second global focusing Fg_2, by which the plurality of first individual particle beams 3 can be imaged on the object 7 at the second operating point A_2. Here, too, the second global focusing Fg_2 may have already been ascertained in advance, e.g. likewise in a calibration.

In a further method step S8 there is the ascertainment of a second global offset d_2 from the second global focusing Fg_2 on the basis of the second beam current I_2. Once again, the ascertainment may have already been implemented in advance, e.g. during a calibration.

In a further method step S9 there is the determination of a second global detuned focusing F_detune_2 on the basis of the second global offset d_2. This determination may likewise have been implemented in advance.

In a further method step S10 there is the raster scanning of the object 7 with the plurality of first individual particle beams 3 at the second operating point A_2 with the second global detuned focusing F_detune_2 for a performance increase. The raster scan can be complete or partial or at points.

Naturally, the method can be repeated for one or more further operating points A_i. In this case, it is possible that the further operating points A_i differ not only in terms of beam current I_i but also in terms of further parameters.

Optionally, the method may moreover comprise the selection of an inspection task or work task. For example, such an inspection task can be a dimension measurement, such as a line width measurement or resolution measurement. For example, a work task can be a material ablation, such as microprocessing using ions, or a targeted material buildup, for example using the use of electron beams. An ascertainment of a corresponding global offset d_i can then be implemented on the basis of the inspection task or on the basis of the work task.

Moreover, it is possible for the described method to be integrated in an autofocus method. In this case, the method may moreover comprise the following steps for example: ascertaining actual autofocus data when raster scanning the object 7; dynamically correcting the global optimal focusing Fg_i on the basis of the actual autofocus data; and dynamically varying the global detuned focusing F_detune_i on the basis of the dynamic correction of the global optimal focusing Fg_i. In this embodiment of the disclosure, the detuning can thus also be taken into account in a fast autofocus correction. However, depending on the size of the detuning to be set, it is also possible that detuning is realized statically, for example by a certain setting of the objective lens, as an offset so to speak. Other realizations are also possible.

A further optional method step contains the correction of a telecentricity error at an operating point A_i on the basis of the ascertained associated global offset d_i. For example, this telecentricity error can be corrected by a setting of a condenser lens system or else by a setting of a multi-deflector array in an intermediate image plane. The correction itself can be implemented statically or in low-frequency fashion.

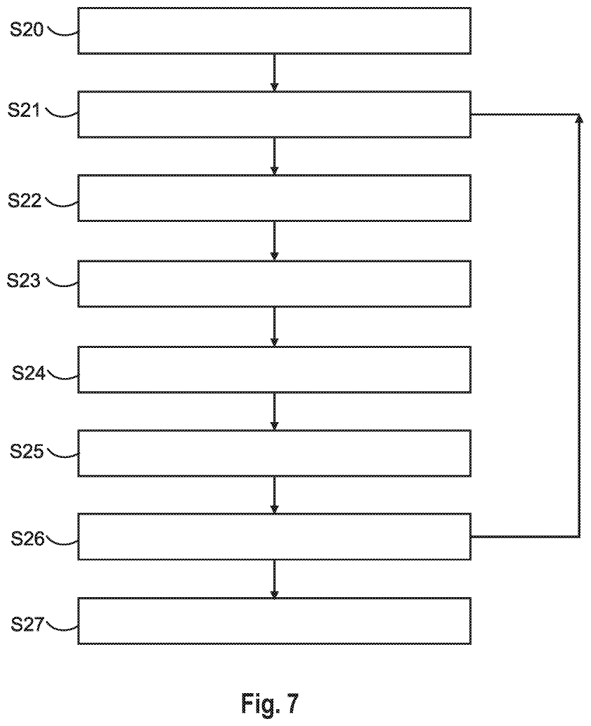

By way of example, FIG. 7 shows a flowchart of a calibration method for a multiple particle beam system 1. The multiple particle beam system operates with a plurality N of first individual charged particle beams 3, wherein the plurality N of first individual particle beams are arranged in a first raster arrangement, are imaged on an object 7 at incidence locations 5 which form a second raster arrangement and are guided over the object 7 using a collective scan deflector 500 arranged in a crossover region of the first individual particle beams 3. Moreover, second individual particle beams 9 emanating from the incidence locations 5 on the object 7 are in each case detected by a detection system 200, which comprises a particle multi-detector 209. In addition, the multiple particle beam system 1 comprises a data capture and data processing unit 10.

The described multiple particle beam system 1 is provided in an initial method step S20.

A first operating point A_1 of the multiple particle beam system 1 with a first beam current I_1 is set in a method step S21.

In a method step S22 there is, at the first operating point A_1, the recording of a focus series of a reference object 7 using the plurality of first individual particle beams 1 and the creation and storing of digital images of the focus series using the detection system 200 and the data capture and data processing unit 10.

In a further method step S23 there is the analysis of the digital images and the ascertainment of a best global focus location Fg_11 using a first algorithm.

In a method step S24 there is the analysis of the digital images and the ascertainment of a further best global focus location Fg_12 using a second algorithm. In this case, the first algorithm and the second algorithm differ from one another. For example, the first algorithm can operate on the basis of an image sharpness criterion and the second algorithm can operate for example on the basis of a contrast gradient method. The two algorithms are sensitive to different image content.

In a further method step S25 there is the determination of an offset d_1 between the best global focus location Fg_11 and the further best focus location Fg_12. This offset arises from the different sensitivities of the two algorithms. In this case, the best global focus location Fg_11 may correspond to the best global focus location Fg_1, and the further best global focus location Fg_12 may correspond to the best global detuned focus location F_detune_1.

In a further method step S26 there is the storage of the offset d_1 in the data capture and data processing unit 10 in relation to the first beam current I_1.

Method steps S21 to S26 can be repeated for one or more further operating points A_i.

The method ends in a final method step S27. The multiple particle beam system 1 is then fully calibrated.

Instead of a calibration method, it is then also possible to determine deviating best global focus locations Fg_i1 and Fg_i2 using various algorithms on the basis of a model of the multiple particle beam system 1. From this, it is likewise possible to determine a corresponding offset d_i, which is then stored in relation to the associated beam current I_i.

The exemplary embodiments of the disclosure described should not be construed as restrictive but only as examples of the disclosure.

### LIST OF REFERENCE SIGNS

1 Multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
101 Object plane
102 Objective lens
103 Field lens
105 Axis
200 Detector system
205 Projection lens system
206 Projection lens
207 Multi-particle detector
208 Projection lens
209 Projection lens
210 Projection lens
212 Crossover
214 Aperture filter, contrast stop
220 Multi-aperture corrector, individual deflector array
222 Collective anti-deflection system
300 Beam generating apparatus
301 Particle source
303 Collimation lens system
305 Multi-aperture arrangement, multi-beam particle generator
306 Micro-optics with multi-aperture plates
307 Field lens
308 Field lens
309 Particle beam
321 Intermediate image plane
323 Beam foci
400 Beam splitter, magnet arrangement
500 Collective beam deflector
503 Voltage source
600 Displacement stage or positioning device
701 Beam trajectory
702 Beam profile
703 Beam profile
704 Curve of the image sharpness
705 Curve of the contrast gradient
706 Curve of the offset as a function of beam current
707 Curve of the resolution of individual particle beam 1
708 Curve of the resolution of individual particle beam 2
d Offset
Z Particle-optical axis

1. A method of operating a multiple particle beam system with a plurality of first
individual charged particle beams imaged on an object in a raster arrangement and guided over the object using a collective scan deflector arranged in a crossover region of the first individual particle beams, the method comprising:
defining a first operating point of the multiple particle beam system comprising a first beam current;
ascertaining a best first global focusing by which the plurality of first individual particle beams is imageable on the object at the first operating point;
ascertaining a first global offset from the best first global focusing based on the first beam current;
ascertaining a first global detuned focusing based on the first global offset; and
raster scanning the object with the plurality of first individual particle beams at the first operating point with the first global detuned focusing.

2. The method of claim 1, further comprising:
selecting an inspection task comprising a member selected from the group consisting of an inspection task and a work task; and
ascertaining the first global offset based on the inspection task.

3. The method of claim 1, further comprising ascertaining the first global offset based on a dimension measurement.

4. The method of claim 1, further comprising ascertaining the first global offset based on a work task comprising a member selected from the group consisting of a material ablation and a targeted material buildup.

5. The method of claim 1, further comprising:
ascertaining actual autofocus data when raster scanning the object;
dynamically correcting the best first global optimal focusing based on the actual autofocus data; and
dynamically varying the first global detuned focusing based on the dynamic correction of the best first global optimal focusing.

6. The method of claim 1, further comprising:
defining a second operating point of the multiple particle beam system comprising a second beam current;
ascertaining a best second global focusing by which the plurality of first individual particle beams is imageable on the object at the second operating point;
ascertaining a second global offset from the best second global focusing base on the second beam current;
determining a second global detuned focusing based on the second global offset; and
raster scanning the object with the plurality of first individual particle beams at the second operating point with the second global detuned focusing.

7. The method of claim 6, wherein the first beam current is different from the second beam current, and the first global offset is different from the second global offset.

8. The method of claim 6, further comprising:
ascertaining actual autofocus data when raster scanning the object at the second operating point;
dynamically correcting the best second global optimal focusing based on the actual autofocus data; and
dynamically varying the second global detuned focusing based on the dynamic correction of the second global focusing.

9. The method of claim 1, further comprising correcting a telecentricity error at the first operating point based on the first global offset.

10. The method of claim 1, wherein the first operating point is defined by a further parameter, and ascertaining the first best global focusing is based the further parameter.

11. One or more machine readable hardware storage devices comprising instructions that are executable by one or more processing devices to perform operations comprising the method of claim 1.

12. A system, comprising:
one or more processing devices; and
one or more machine readable hardware storage devices comprising instructions that are executable by the one or more processing devices to perform operations comprising the method of claim 1.

13. A calibration method for a multiple particle beam system operating with a plurality of first individual charged particle beams arranged in a first raster arrangement and imaged on an object at incidence locations defining a second raster arrangement, the first individual particle beams being guided over the object using a collective scan deflector in a crossover region of the first individual particle beams, with second individual particle beams emanating from the incidence locations of the object being detected in each case by a detection system comprising a particle multi-detector and with the multiple particle beam system comprising a data capture and data processing unit, the calibration method comprising:
setting a first operating point of the multiple particle beam system with a first beam current;
at the first operating point, recording a focus series of a reference object using the plurality of first individual particle beams and creating and storing digital images of the focus series using the detection system and the data capture and data processing unit;
analysing the digital images and ascertaining a first best global focus location using a first algorithm;
analysing the digital images and ascertaining a second best global focus location using a second algorithm;
determining an offset between the first and second best global focus locations; and
storing the offset in the data capture and processing unit in relation to the first beam current.

14. The method of claim 13, further comprising repeating the method at at least one further operating point.

15. The method of claim 13, further comprising:
setting a second operating point of the multiple particle beam system with a second beam current;
at the second operating point, recording a focus series of a reference object using the plurality of first individual particle beams and creating and storing digital images of the focus series using the detection system and the data capture and data processing unit;
analysing the digital images and ascertaining a best global focus location using the first algorithm;
analysing the digital images and ascertaining a further best global focus location using the second algorithm;
determining an offset between the best global focus location and the further best global focus location; and
storing the offset in the data capture and processing unit in relation to the second beam current.

16. (canceled)

17. (canceled)

18. The method of claim 13, wherein the first best global focus at the first operating point for some but not all of the plurality first individual particle beams with in each case an individual best focus is ascertained as an arithmetic mean of the individual foci.

19. The method of claim 13, wherein the first best global focus at the first operating point for some but not all of the plurality of first individual particle beams with in each case an individual best focus is formed as an arithmetic mean of a maximum individual focus and a minimum individual focus.

20. One or more machine readable hardware storage devices comprising instructions that are executable by one or more processing devices to perform operations comprising the method of claim 13.

21. A system, comprising:
one or more processing devices; and
one or more machine readable hardware storage devices comprising instructions that are executable by the one or more processing devices to perform operations comprising the method of claim 13.

22. A multiple particle beam system, comprising:
a multi-beam particle generator configured to generate a first field of a plurality of first individual charged particle beams;
a first particle-optical unit with a first particle-optical beam path, the first particle-optical unit configured to image the first individual particle beams on a wafer surface in an object plane so that the first individual particle beams are incident on the wafer surface at incidence locations which define a second field;
a detection system comprising a plurality of detection regions defining a third field;
a second particle-optical unit with a second particle-optical beam path, the second particle-optical unit configured to image second individual particle beams emanating from the incidence locations in the second field on the third field of the detection regions of the detection system;
a magnetic and/or electrostatic objective lens configured to have both the first and the second individual particle beams pass therethrough;
a beam splitter in the first particle-optical beam path between the multi-beam particle generator and the objective lens, the beam splitter in the second particle-optical beam path between the objective lens and the detection system;
a collective first scan deflector configured to collectively scan the first individual charged particle beams over the object, the object in a crossover region a crossover region of the first individual charged particle beams in the first particle-optical beam path;
a sample stage configured to hold and/or position a wafer during a wafer inspection;
an autofocus measuring element configured to create measurement data for ascertaining actual autofocus data during the wafer inspection;
a fast autofocus correction lens;
a controller having a data processing and storage unit; and
an autofocus correction mode selection device configured to select: i) a first autofocus correction mode which is beam current-independent in view of an autofocus correction; and ii) a second autofocus correction mode which is beam current-dependent in view of the autofocus correction,
wherein:
the controller is configured to control particle-optical components in the first and/or in the second particle-optical beam path;
the controller is configured for static or low-frequency adaptation of a focusing to control the objective lens and/or an actuator of the sample stage at an operating point with a beam current and a working distance so that the first individual particle beams are focused on the wafer surface situated at the working distance;
the controller is configured for high-frequency adaptation of the focusing in the first autofocus correction mode to create an autofocus correction lens control signal based on the actual autofocus data at the operating point during the wafer inspection to control the fast autofocus correction lens during the wafer inspection at the operating point;
the controller is configured for high-frequency adaptation of the focusing in the second autofocus correction mode to create an autofocus correction lens control signal based on the actual autofocus data and based on the beam current at the operating point during the wafer inspection to control the fast autofocus correction lens in high-frequency fashion during the wafer inspection at the operating point and/or to control the objective lens in static or low-frequency fashion during the wafer inspection at the operating point so that the first individual particle beams are focused in detuned fashion on the wafer surface situated at the working distance.

23. (canceled)

24. (canceled)

25. (canceled)
